(19) United States
(12) Patent Application Publication
(10) Pub. No.: US 2009/0162562 A1
(43) Pub. Date: Jun. 25, 2009

(54) Methods for Applying Thermal Barrier Coating Systems

(76) Inventors: Bangalore Aswatha Nagaraj, West Chester, OH (US); David John Wortman, Hamilton, OH (US); Nicole Marie Polley, Cincinnati, OH (US); William Bryan Connor, Mason, OH (US); Roger Dale Wustman, Mason, OH (US)

Correspondence Address: GENERAL ELECTRIC COMPANY, GE AVIATION, ONE NEUMANN WAY MD H17, CINCINNATI, OH, 45215, US

(21) Appl. No.: 11/963,995

(22) Filed: Dec. 24, 2007

(51) Int. Cl. C23C 16/00; B05D 3/02; B05D 1/36; B05D 1/38; C23C 4/08; H05H 1/24

(52) U.S. Cl. 427/456; 427/402; 427/255.7; 427/372.2; 427/569

(57) ABSTRACT

Methods for coating a substrate includes depositing on the substrate, a inner bond coat layer of a bond coat composition comprising, in weight percent, 14-20% Cr, 5-8% Al, 8-12% Co, 3-7% Ta, 0.1-0.6% Hf, 0.1-0.5% Y, up to about 1% Si, 0.005-0.020% Zr, 0.04-0.08% C, 0.01-0.02% B, with a remainder including nickel (Ni) and incidental impurities, wherein the bond coat composition is substantially free of rhenium; forming an aluminum-containing layer overlying the inner bond coat layer; and, optionally, depositing a thermal barrier coating composition overlying the aluminum-containing layer.

### BACKGROUND OF THE INVENTION

This invention relates generally to method for applying thermal barrier coating systems, and more particularly to methods for applying thermal barrier coating systems using deposition processes adapted to provide desired outcomes.

In the art of gas turbine engines, particularly those developed for use in aircraft, high temperature operating components are exposed to strenuous oxidizing conditions during operation. Typical of such components are the blades, vanes and associated parts disposed in the turbine section of such engines. In order to extend the operating life of such articles, designers have specified coatings for application to article surfaces.

One such coating is a thermal barrier coating system. Generally, the thermal barrier coating is a ceramic type coating, examples of which include zirconia generally stabilized with yttria, magnesia or calcia. The coating system may include a bond coating disposed between the substrate and the ceramic thermal barrier coating. The bond coat may be a so-called aluminide (diffusion) or “McrAlY” types, where M signifies one or more of cobalt, iron, nickel, and mixtures and alloys thereof. Other elements including Y, rare earths, Pt, Rh, Pd, Hf, etc., and their combinations have been included in such McrAlY type alloys to enhance selected properties.

The bond coat may include an aluminum-containing layer formed by an aluminiding process. One such inter-layer is described in U.S. Pat. No. 4,880,614 to Strangman, et al. In an exemplary embodiment, the aluminum-containing layer comprises at least about 12 weight percent aluminum.

U.S. Pat. No. 5,236,745 discloses a strengthened nickel base overlay bond coat with overaluminide layer which is utilized under the thermal barrier coating to provide improved protection at high temperatures to engine components. The nominal composition of this nickel base overlay bond coat, in weight percent, is 18 Cr, 6.5 Al, 10 Co, 6 Ta, 2 Re, 0.5 Hf, 0.3 Y, 1 Si, 0.015 Zr, 0.06 C, 0.015 B, with the balance Ni and incidental impurities.

However, the bond coat discussed above includes rhenium, an increasingly expensive and scarce alloying element. Accordingly, it would be desirable to provide a strengthened bond coat, compatible with an overaluminide layer, that is substantially free of rhenium. It would also be desirable to provide a coating system utilizing a strengthened, rhenium-free bond coat for high temperature components. Further, it would be desirable to provide methods for coating a substrate with thermal barrier coating systems in order to control the coating microstructure to enhance high temperature performance.

### BRIEF DESCRIPTION OF THE INVENTION

An exemplary embodiment provides a method for coating a substrate. The exemplary method includes depositing on the substrate, a inner bond coat layer of a bond coat composition comprising, in weight percent, 14-20% Cr, 5-8% Al, 8-12% Co, 3-7% Ta, 0.1-0.6% Hf, 0.1-0.5% Y, up to about 1% Si, 0.005-0.020% Zr, 0.04-0.08% C, 0.01-0.02% B, with a remainder including nickel (Ni) and incidental impurities, wherein the bond coat composition is substantially free of rhenium; forming an aluminum-containing layer overlying the inner bond coat layer; and optionally, depositing a thermal barrier coating composition overlying the aluminum-containing layer.

### BRIEF DESCRIPTION OF THE DRAWINGS

The subject matter which is regarded as the invention is particularly pointed out and distinctly claimed in the concluding part of the specification. The invention, however, may be best understood by reference to the following description taken in conjunction with the accompanying drawing figures in which:

FIG. 1 is a cross-sectional diagrammatic view through a metal article having an exemplary thermal barrier coating system.

FIG. 2 is flow chart of exemplary processes for coating an article with a thermal barrier coating system.

### DETAILED DESCRIPTION OF THE INVENTION

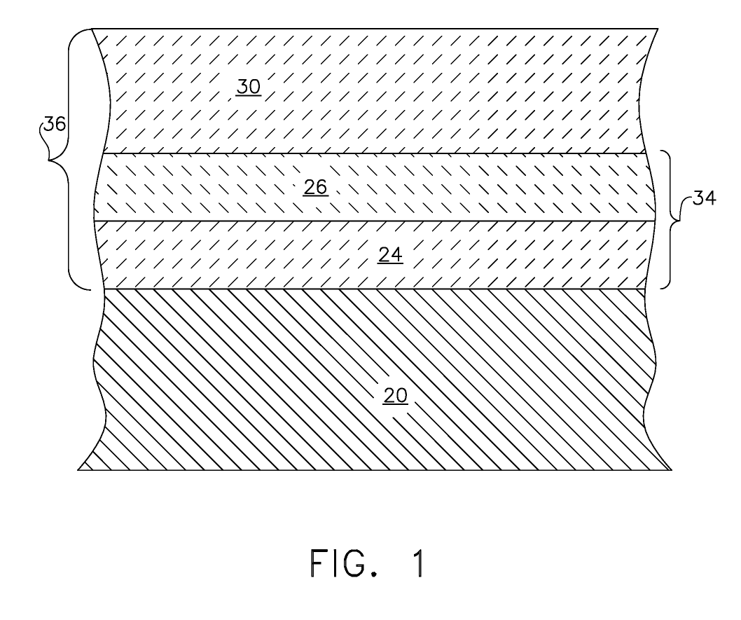

Referring to the drawings wherein identical reference numerals denote the same elements throughout the various views, FIG. 1 shows a superalloy substrate 20 provided with a multi-layer thermal barrier coating system including a bond coat inner layer 24, an aluminum-containing layer 26, and a thermal barrier coating 30. The bond coat inner layer 24 and the aluminum-containing layer 26 collectively form a bond coat 34. The bond coat 34 and thermal barrier coating 30 collectively form a thermal barrier coating system 36. The “bond coat” may be called an “environmental coating” in the absence of a thermal barrier coating 30. In certain exemplary embodiments, the aluminide layer 26 may be a precious metal modified aluminide layer as discussed in greater detail below.

In an exemplary embodiment, substrate 20 represents an article such as a turbine blade or vane, shroud, nozzle, combustor, or other component of a gas turbine engine for use in a high temperature environment. The substrate 20 may comprise a nickel or cobalt base superalloy. The substrate 20 may represent a single crystal (SX), directionally solidified (DS), or polycrystalline article.

At least a portion of substrate 20 is overlaid with a bond coat inner layer 24. Embodiments disclosed herein provide a composition for a strengthened overlay bond coat inner layer 24. The bond coat inner layer 24, as deposited, may include, in weight percent: 14-20% Cr, 5-8% Al, 8-12% Co, 3-7% Ta, 0.1-0.6% Hf, 0.1-0.5% Y, up to about 1% Si, 0.005-0.020% Zr, 0.04-0.08% C, 0.01-0.02% B, with a remainder including nickel (Ni) and incidental impurities. In an exemplary embodiment, the sulfur content is less than about 0.001%. An exemplary composition nominally includes, in weight percent: 18% Cr, 6.5% Al, 10% Co, 6% Ta, 0.5% Hf, 0.3% Y, 1% Si, 0.015% Zr, 0.06% C, 0.015% B, with the remainder being nickel and incidental impurities. As discussed in greater detail below, the exemplary bond coat inner layer 24 may be deposited onto substrate 20 with varying deposition techniques, depending on desired microstructure, thickness, and other characteristics. In certain exemplary embodiments inner layer 24 may be between about 1-3 mils (25.4-76.2 microns) thick. In an exemplary embodiment, inner layer 24 is about 2 mils (50.8 microns) thick. In other exemplary embodiments, inner layer 24 may be between about 6 mils (152 microns) thick. The thickness of inner layer 24 may be associated with the deposition process as discussed below. The relative smoothness (roughness) of the deposited inner layer 24 may be associated on the deposition process.

In an exemplary embodiment, the bond coat inner layer 24 is overlaid with an aluminum-containing layer 26. The aluminum-containing layer 26 may be modified with a “precious metal” such as platinum (Pt), rhodium (Rh), iridium (Ir), or palladium (Pd).

In an exemplary embodiment, the aluminum-containing layer 26 may be deposited through an “aluminiding or “aluminizing” process. In an exemplary embodiment, as deposited, the aluminum-containing layer may include about 12 to about 30% by weight aluminum (Al). In an exemplary embodiment, the aluminum-containing layer may include about 15 to about 25% by weight Al. In an exemplary embodiment, the aluminum-containing layer comprises at least about 12% by weight aluminum.

An exemplary coating system 36 also includes a thermal barrier coating 30 overlying the bond coat 34. In an exemplary embodiment, the thermal barrier coating includes a yttria-stabilized zirconia (YSZ) composition. A commonly used YSZ includes about 8 weight % yttria. Other thermal barrier coating compositions compatible with the disclosed strengthened bond coat are contemplated within the scope of this disclosure in order to provide, for example, lower thermal conductivity, improved erosion resistance and improved impact resistance.

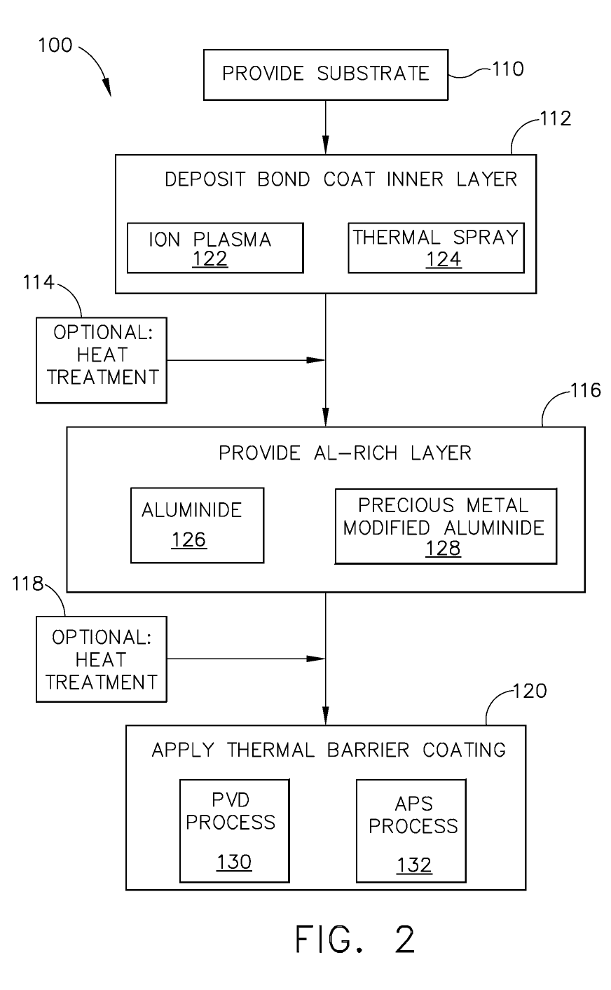

Exemplary coating processes 100 are illustrated in FIG. 2. The general process steps include: providing a substrate (Step 110), depositing a bond coat inner layer onto at least a portion of the substrate (Step 112), performing an optional heat treatment (Step 114), providing an aluminum-containing outer layer (Step 116), performing an optional heat treatment (Step 118), and optionally, applying a thermal barrier coating (Step 120).

In an exemplary embodiment, Step 112 may be accomplished by at least two separate deposition techniques, depending on the component to be coated, the desired microstructure of the bond coat inner layer, or other considerations. For example, in an exemplary embodiment, the overlay bond coat inner layer is deposited onto the substrate by an ion plasma deposition process (Sub-step 122). The ion plasma deposition process enables the production of a “thin” bond coat inner layer (from about 1 to about 3 mils (25.4-76.2 microns) thick) having a relatively smooth texture. In an exemplary embodiment, the thin bond coat layer may be about 2 mils (50.8 microns) thick. Application of a thin bond coat layer using ion plasma deposition is particularly advantageous for advanced turbine blade design as the deposition process can be controlled to avoid closing off the cooling holes.

Following deposition of the exemplary bond coat inner layer using ion plasma deposition, an aluminum-containing outer layer may be provided thereon using a diffusion process such as vapor phase deposition or pack process as is well known in the art (Sub-step 126). Other methods of application, including for example spray methods, chemical vapor deposition, in-pack methods, laser methods, and others may be used for application of the aluminum-containing layer.

Optionally, the aluminide layer may be a precious metal modified aluminide. An exemplary process (Sub-step 128) includes applying a thin layer (about 0.1 to about 0.2 mils, 0.25-0.51 microns) of a precious metal over the bond coat inner layer by a suitable technique, such as electroplating, although the process is not so limited. The precious metal layer is then subjected to a diffusion aluminide coating process (as discussed above) to provide the precious metal modified aluminide layer.

In an exemplary embodiment, prior to the aluminiding step, the coated substrate may be subjected to an optional heat treatment (Step 114) at a temperature from about 1600° F. to about 2150° F. (871-1177° C.). In an exemplary embodiment, the optional heat treatment temperature is from about 1850° F. to about 1950° F. (1010-1066° C.). The optional heat treatment may have a duration of from about 1 to about 8 hours. An exemplary heat treatment has a duration of from about 2 to about 4 hours.

In an exemplary embodiment, a similar heat treatment (Step 118) may optionally be utilized subsequent to the aluminiding process. That is, subsequent to the aluminiding step, the coated substrate may be heat treated at a temperature from about 1600° F. to about 2150° F. (871-1177° C.), or alternately 1850° F. to about 1950° F. (1010-1066° C.), for 1 to 8 hours, or alternately from about 2 to about 6 hours.

In an exemplary embodiment, a columnar thermal barrier coating is deposited onto the bond coat by a physical vapor deposition process (Sub-step 130) such as electron beam physical vapor deposition (EB-PVD). Particularly for turbine blades, the ion plasma deposited inner bond coat layer and diffusion aluminide layer, in combination with a physical vapor deposited TBC provides a controlled coating system able to provide improved strength, creep resistance, oxidation resistance, and spallation resistance.

Another exemplary embodiment utilizes the same or similar composition for a bond coat inner layer, but employs a thermal spray technique (Sub-step 124), such as a plasma spray, for deposition of the bond coat inner layer onto the substrate. The bond coat inner layer as deposited, may comprise, in weight percent: 14-20% Cr, 5-8% Al, 8-12% Co, 3-7% Ta, 0.1-0.6% Hf, 0.1-0.5% Y, up to about 1% Si, 0.005-0.020% Zr, 0.04-0.08% C, 0.01-0.02% B, with a remainder including nickel (Ni) and incidental impurities. In an exemplary embodiment, the sulfur content is less than about 0.001%. An exemplary composition nominally includes, in weight percent: 18% Cr, 6.5% Al, 10% Co, 6% Ta, 0.5% Hf, 0.3% Y, 1% Si, 0.015% Zr, 0.06% C, 0.015% B, with the remainder being nickel and incidental impurities.

The bond coat inner layer deposited onto a substrate using a thermal spray technique exhibits a rougher surface than a bond coat inner layer deposited using an ion plasma technique. For example, the bond coat inner layer, deposited with a thermal spray technique, such as plasma spraying, may have a surface roughness of from about 200-600 microinches (about 5.1-15.3 microns) RA, as taught in U.S. Pat. No. 5,236,745. Additionally, the exemplary bond coat inner layer deposited by a thermal spray process may be thicker than the inner layer deposited by an ion plasma process. The exemplary bond coat inner layer may be applied to a thickness of from about 2-15 mils (51-381 microns). In an exemplary embodiment, the thermally sprayed bond coat inner layer may be about 8 mils (203 microns) thick. Gas turbine engine components such as nozzles, shrouds, and combustors may be coated with an exemplary bond coat composition by a thermal spray process.

The bond coat for an exemplary coating system further includes an aluminum-containing outer layer on the bond coat inner layer using a diffusion aluminiding process (Sub-step 126). In an exemplary embodiment, the aluminum-containing layer may include about 12 to about 30% by weight Al. In another exemplary embodiment, the aluminum-containing layer may include about 15 to about 25% by weight Al.

Optionally, the exemplary bond coat inner layer may be overlaid with a precious metal modified aluminide layer by a process as described above (Sub-step 128). The thermally sprayed bond coat inner layer and the aluminum-containing layer (aluminide or precious metal modified aluminide) collectively form the bond coat for a subsequently applied TBC, or an environmental coating in the absence of an applied TBC.

In an exemplary embodiment, a thermal barrier coating is deposited onto the bond coat by a plasma spray process, such as air plasma spray (APS) (Sub-step 132), as described in U.S. Pat. No. 5,236,745, and incorporated herein by reference. In an exemplary embodiment, the surface roughness of the thermally sprayed bond coat inner layer is retained during the aluminiding process, and serves as an anchor for the thermal barrier coating.

In an exemplary coating process, the application of the bond coat inner layer may be followed by a suitable heat treatment (Step 114) as set forth above. Alternately, or additionally, the aluminiding step may be followed by a suitable heat treatment (Step 118).

### Example 1

Two groups of samples were prepared. In the first group, approximately 0.006 inches (0.15 mm) of a known bond coat composition was deposited onto one-inch (2.54 cm) diameter/0.125 inch (3.2 mm) thick Rene N5 (without yttrium) superalloy specimens. The bond coat composition was, in nominal weight %: 18Cr, 6.5Al, 10Co, 6Ta, 2Re, 0.3Y, 1Si, 0.015Zr, 0.06C, 0.5Hf, 0.015B, with the balance Ni and incidental impurities. The composition of the Rene N5 (without yttrium) was, in nominal weight %: 7Cr, 6.2Al, 7.5Co, 6.5Ta, 5 W, 3Re, 1.5Mo, 0.05C, 0.15Hf, 0.004B, with the balance Ni and incidental impurities.

In the second group, approximately 0.006 inches (0.15 mm) of a bond coat composition (disclosed herein) was deposited onto one-inch diameter (2.54 cm)/0.125 inch (3.2 mm) thick Rene N5 (without yttrium) superalloy specimens. The bond coat composition included, in nominal weight %: 18Cr, 6.5Al, 10Co, 6Ta, 0.3Y, 1Si, 0.015Zr, 0.06C, 0.5Hf, 0.015B, with the balance Ni and incidental impurities.

The powder size distribution of the two bond coat compositions were substantially identical. As deposited, both bond coat compositions had a surface roughness of approximately 400 microinches (about 10.6 microns).

Both groups of specimens were then deposited with a vapor phase diffusion aluminide coating, deposited at approximately 1975° F. (1079° C.) for four hours. Thereafter, one side of both groups of specimens was deposited with approximately 0.012 inches (about 0.3 mm) of a thermal barrier coating (zirconia stabilized with approximately 8 weight percent yttria), using an air plasma spray process.

The samples were tested by a thermal cycling procedure to determine the durability of the thermal barrier coating. In this procedure, the samples were heated to a temperature of about 2000° F. (1093° C.) in eight minutes, held at temperature for 45 minutes, then cooled to below 200° F. (93° C.) in approximately 10 minutes, to complete one cycle. The cycled samples were examined every 20 cycles.

After 100 cycles of testing, both groups of specimens showed no loss of the thermal barrier coating. Thus, it is believed that the bond coat compositions disclosed herein provide acceptable replacement for the known bond coat composition which nominally includes about 2 weight % Re.

The exemplary embodiments disclosed herein provide a thermal barrier coated article including a coating system having good mechanical properties, good high temperature environmental resistance, and spallation resistance of the TBC from underlying portions of the coating system or from the article substrate. The coated article can be used at higher operating temperatures because of such combination of properties and characteristics.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A method for coating a substrate comprising:
depositing on the substrate, a inner bond coat layer of a bond coat composition comprising, in weight percent, 14-20% Cr, 5-8% Al, 8-12% Co, 3-7% Ta, 0.1-0.6% Hf, 0.1-0.5% Y, up to about 1% Si, 0.005-0.020% Zr, 0.04-0.08% C, 0.01-0.02% B, with a remainder including nickel (Ni) and incidental impurities, wherein the bond coat composition is substantially free of rhenium;
forming an aluminum-containing layer overlying the inner bond coat layer; and
optionally, depositing a thermal barrier coating composition overlying the aluminum-containing layer.

2. The method according to claim 1 wherein depositing the inner bond coat layer includes a deposition process selected from ion plasma deposition and thermal spray deposition.

3. The method according to claim 1 wherein forming the aluminum-containing layer includes diffusing aluminum or an aluminum alloy into an outer portion of the bond coat layer.

4. The method according to claim 1 wherein depositing the thermal barrier coating composition includes a deposition process selected from physical vapor deposition and air plasma spray.

5. The method according to claim 1 including, subsequent to depositing the bond coat inner layer on the substrate, subjecting the coated substrate to a suitable heat treatment prior to forming the aluminum-containing layer.

6. The method according to claim 1 including, subsequent to forming the aluminum containing layer, subjecting the coated substrate to a suitable heat treatment.

7. The method according to claim 2 wherein the selected deposition process is ion plasma deposition, and wherein depositing the thermal barrier coating composition includes physical vapor deposition.

8. The method according to claim 2 wherein the selected deposition process is thermal spray deposition, and wherein depositing the thermal barrier coating composition includes air plasma spray.

9. The method according to claim 1 wherein depositing the inner bond coat layer includes depositing a bond coat composition comprising, in weight percent: about 18% Cr, about 6.5% Al, about 10% Co, about 6% Ta, about 0.5% Hf, about 0.3% Y, up to about 1% Si, about 0.015% Zr, about 0.06% C, about 0.015% B, with a remainder including nickel (Ni) and incidental impurities, wherein the bond coat composition is substantially free of rhenium.

10. The method according to claim 1 wherein depositing the inner bond coat layer includes depositing a bond coat composition consists of, in weight percent: about 18% Cr, about 6.5% Al, about 10% Co, about 6% Ta, about 0.5% Hf, about 0.3% Y, about 1% Si, about 0.015% Zr, about 0.06% C, about 0.015% B, with a remainder including nickel (Ni) and incidental impurities, wherein the bond coat composition is substantially free of rhenium.

11. The method according to claim 1 wherein depositing the inner bond coat layer includes utilizing ion plasma to deposit a sufficient amount of the bond coat composition to provide the inner bond coat layer with a thickness of between about 1-3 mils.

12. The method according to claim 11 wherein depositing the thermal barrier coating composition includes utilizing physical vapor deposition.

13. The method according to claim 1 wherein depositing the inner bond coat layer includes utilizing thermal spray deposition to deposit a sufficient amount of the bond coat composition to provide the inner bond coat layer with a thickness of between about 2-15 mils.

14. The method according to claim 13 wherein depositing the thermal barrier coating composition includes utilizing air plasma spray.

15. The method according to claim 3 including, prior to diffusing the aluminum alloy, applying a layer of metal over the bond coat inner layer, wherein the metal is at least one element selected from the group consisting of platinum (Pt), rhodium (Rh), iridium (Ir), or palladium (Pd).

16. The method according to claim 1 wherein forming the aluminum-containing layer includes diffusing aluminum or an aluminum alloy throughout the entire bond coat layer.
